(19) United States
(12) Patent Application Publication
(10) Pub. No.: US 2026/0328856 A1
(43) Pub. Date: Oct. 22, 2026

(54) CHARGER AND OCV DATA ACQUISITION METHOD

(71) Applicant: MURATA MANUFACTURING CO., LTD., Kyoto (JP)

(72) Inventor: Koji HATTORI, Kyoto (JP)

(21) Appl. No.: 19/468,173

(22) Filed: Feb. 3, 2026

Related U.S. Application Data
(63) Continuation of application No. PCT/JP2024/020000, filed on May 31, 2024.

(30) Foreign Application Priority Data
Aug. 22, 2023 (JP) 2023-134534

(51) Int. Cl. G01R 31/392; G01R 31/378; G01R 31/3835; H02J 7/80; H02J 7/96

(52) U.S. Cl. CPC G01R 31/392; G01R 31/378; G01R 31/3835; H02J 7/80; H02J 7/96

(57) ABSTRACT

A charger includes a control unit, a voltage measurement unit, and an OCV data extraction unit. The control unit controls charging of a secondary battery when the secondary battery is attached to the charger. The voltage measurement unit measures a terminal voltage of the secondary battery during charging. The OCV data extraction unit extracts OCV data that can be used to analyze the deterioration degree of the secondary battery. The charger has a first mode and a second mode as one cycle of charging of the secondary battery. In the first mode, the control unit charges the secondary battery with a predetermined current value. The voltage measurement unit measures a terminal voltage value (α) of the secondary battery. The control unit and the voltage measurement unit shift to the second mode after the end of the first mode. In the second mode, the control unit suspends charging for a predetermined suspension time. The voltage measurement unit measures the OCV value (β) of the secondary battery immediately after the elapse of the suspension time. The control unit and the voltage measurement unit return to the first mode after the end of the second mode. The control unit compares a terminal voltage value (αA) acquired in the first mode with a terminal voltage value (αB) acquired in the first mode one cycle before the first mode. The control unit controls the first time such that a difference value between the terminal voltage value (αA) and the terminal voltage value (αB) becomes a constant value. The OCV data extraction unit acquires OCV data using the OCV value (β) measured in each of a plurality of cycles.

### CROSS REFERENCE TO RELATED APPLICATIONS

The present application is a continuation of International Patent Application No. PCT/JP2024/020000, filed on May 31, 2024, which claims priority to Japanese Patent Application No. 2023-134534, filed on Aug. 22, 2023, the entire contents of which are incorporated herein by reference.

### BACKGROUND

The present disclosure relates to a technique for acquiring OCV data for OCV deterioration analysis used as one of deterioration analysis methods for secondary batteries.

A battery state estimation method is described in which the battery is discharged from the fully charged state to the lower limit charged state, and the discharge current during that time is integrated to calculate the battery capacity of the battery.

In the battery state estimation method, charging is performed every time a plurality of defined measurement points are reached between the lower limit charged state and the fully charged state, and then charging standby is performed, and the open-circuit voltage of the battery after charging standby is measured. In the battery state estimation method, a correlation characteristic of a battery is acquired based on a charging rate at each measurement point and an open-circuit voltage measured at each measurement point.

### SUMMARY

The present disclosure relates to a technique for acquiring OCV data for OCV deterioration analysis used as one of deterioration analysis methods for secondary batteries.

In the battery state estimation method referenced in the BACKGROUND section, it is merely intended to estimate a deterioration state from a difference in open circuit voltage at a defined measurement point. In addition, as the deterioration of the battery progresses, the measurement cannot be performed when the initial SOC is around 0% and around 100%, and the number of measurement points decreases. Therefore, there is a problem that there is a case where there is no comparison target of defined measurement points.

In an embodiment, the present disclosure relates to perform measurement in which a decrease in the number of measurement points of the OCV value, which causes a decrease in accuracy of deterioration analysis, is suppressed even for a deteriorated battery.

A charger of the present disclosure, in an embodiment, includes a control unit, a voltage measurement unit, and an OCV data extraction unit. The control unit controls charging of a lithium ion secondary battery when the lithium ion secondary battery is attached to the charger. The voltage measurement unit measures a terminal voltage of the lithium ion secondary battery at the time of charging. The OCV data extraction unit extracts OCV data that can be used to analyze the deterioration degree of the lithium ion secondary battery.

The charger has a first mode and a second mode as one cycle of charging of the lithium ion secondary battery according to an embodiment.

In the first mode, in an embodiment, the control unit charges the lithium ion secondary battery at a predetermined current value. The voltage measurement unit measures a terminal voltage value α of the lithium ion secondary battery. The control unit and the voltage measurement unit shift to the second mode after the end of the first mode.

In the second mode, in an embodiment, the control unit suspends charging for a predetermined suspension time. The voltage measurement unit measures an OCV value β of the lithium ion secondary battery immediately after the elapse of the suspension time. The control unit and the voltage measurement unit return to the first mode after the end of the second mode.

The control unit, in an embodiment, compares a terminal voltage value αA acquired in the first mode with a terminal voltage value αB acquired in the first mode one cycle before the first mode. The control unit controls charging in the first mode such that a difference value between the terminal voltage value αA and the terminal voltage value αB becomes a constant value.

The OCV data extraction unit, in an embodiment, extracts the OCV data using the OCV value β measured in each of the plurality of cycles.

In this configuration, in an embodiment, in the lithium ion secondary battery, the terminal voltage value in the 100% charged state and the terminal voltage value in the 0% charged state are substantially constant regardless of the deterioration degree, and a plurality of OCV values are acquired using the terminal voltage values. As a result, the number of measurement points of the OCV value does not decrease in charging for obtaining the SOC-OCV characteristic without being affected by the deterioration degree of the lithium ion secondary battery.

According to an embodiment of the present disclosure, the OCV value can be measured without reducing the number of measurement points for obtaining the SOC-OCV characteristic.

### BRIEF DESCRIPTION OF THE FIGURES

FIGS. 1A and 1B are conceptual diagrams showing capacity before and after deterioration of positive and negative electrodes of a lithium ion secondary battery; and FIG. 1C is a diagram illustrating an example of a relationship between SOC and OCV (before deterioration and after deterioration).

FIG. 2 is a configuration diagram of a charging system including a charger and a secondary battery according to an embodiment of the present disclosure and capable of acquiring OCV data.

FIG. 3A is a graph illustrating an example of a distribution of measurement points according to an embodiment of the present disclosure; and FIG. 3B is a graph illustrating an example of a distribution of measurement points of a conventional example.

FIGS. 4A and 4B are a tables showing a relationship between a combination of a current and a charging time and the number of measurement points according to an embodiment of the present disclosure; and FIG. 4C is a table showing a relationship between a combination of a current and a charging time and the number of measurement points in a conventional example.

FIG. 5 is a flowchart illustrating an example of an OCV data acquisition method according to an embodiment of the present disclosure.

FIG. 6 is a configuration diagram of a charging system capable of acquiring OCV data including a secondary battery including a voltage value output terminal.

### DETAILED DESCRIPTION

The present disclosure will be described below in further detail including with reference to the figures according to an embodiment.

A charger and an OCV data acquisition method according to a first embodiment of the present disclosure will be described with reference to the drawings.

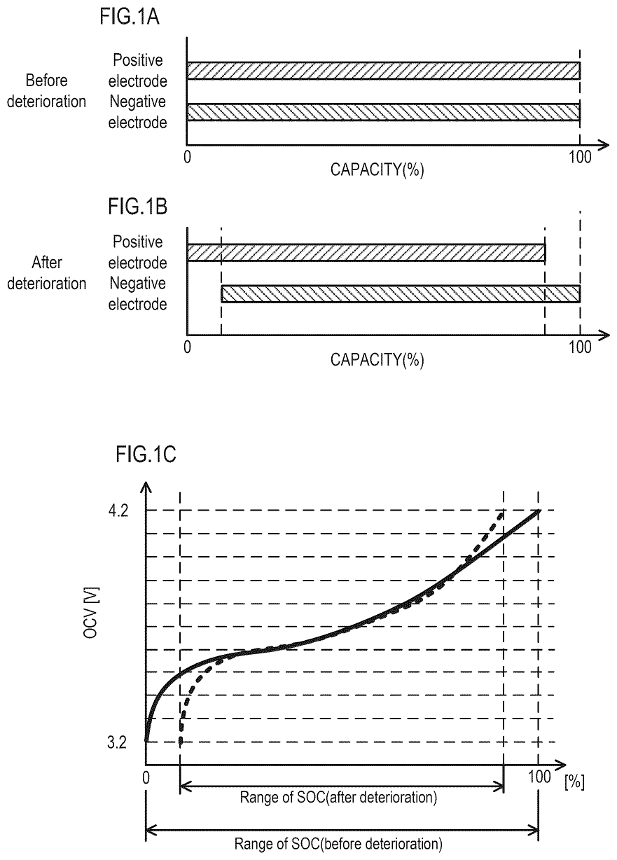

FIGS. 1A and 1B are conceptual diagrams illustrating capacity before and after deterioration of positive and negative electrodes of a lithium ion secondary battery, and FIG. 1C is a diagram illustrating an example of a relationship between SOC and OCV (before deterioration and after deterioration). FIG. 1A illustrates possible ranges of the positive electrode capacity and the negative electrode capacity before deterioration, and FIG. 1B illustrates an example of possible ranges of the positive electrode capacity and the negative electrode capacity after deterioration. In FIG. 1C, the horizontal axis represents the SOC of the lithium ion secondary battery, and the vertical axis represents the OCV. In FIG. 1C, a solid line indicates a state where the deterioration degree is 0%, and a broken line indicates a state where the deterioration degree is advanced to some extent.

The capacity of the lithium ion secondary battery is determined by the amount of lithium ions moving between the positive electrode active material and the negative electrode active material. According to the models of FIGS. 1A and 1B, the capacity of the lithium ion secondary battery is determined by the overlapping range of the range that can be taken by the positive electrode capacity and the range that can be taken by the negative electrode capacity.

As illustrated in FIG. 1A, in the state before deterioration, the entire region where the positive electrode capacity and the negative electrode capacity overlap is the capacity of the lithium ion battery, and the left end represents an SOC of 0% before deterioration, and the right end represents an SOC of 100% before deterioration.

When charging and discharging are repeated, each of the positive electrode active material and the negative electrode active material deteriorates, and as illustrated in FIG. 1B, the range of the capacity that can be taken by each decreases, and the overlap between the range of the positive electrode capacity and the range of the negative electrode capacity decreases. That is, the left end of the negative electrode after deterioration illustrated in FIG. 1B has an SOC of 0%, and the right end of the positive electrode after deterioration has a SOC of 100% after deterioration. As a result, the capacity of the lithium ion secondary battery after deterioration decreases in a range where the positive electrode capacity after deterioration and the negative electrode capacity after deterioration overlap with each other.

Therefore, as indicated by the solid line in FIG. 1C, in the state before deterioration (the state without deterioration), the minimum OCV value (for example, 3.2 V) is obtained when the SOC is 0%, the maximum OCV value (for example, 4.2 V) is obtained when the SOC is 100%, and the OCV value can be measured between 0% and 100% of the SOC.

However, as the deterioration degree increases, a range narrower than the width of the SOC of 0% to the SOC of 100% before deterioration changes to a range of the SOC of 0% to the SOC of 100% after deterioration as indicated by a broken line in FIG. 1B.

For this reason, when an attempt is made to measure the OCV value by intermittent charging at a constant current time with reference to the SOC range before deterioration, the number of measurement points decreases.

On the other hand, as illustrated in FIG. 1C, the maximum value and the minimum value of the OCV value do not change before deterioration and after deterioration. Therefore, by making the difference value of the terminal voltage value between the plurality of measurement points constant, the number of measurement points does not change, and a decrease in the number of measurement points can be suppressed.

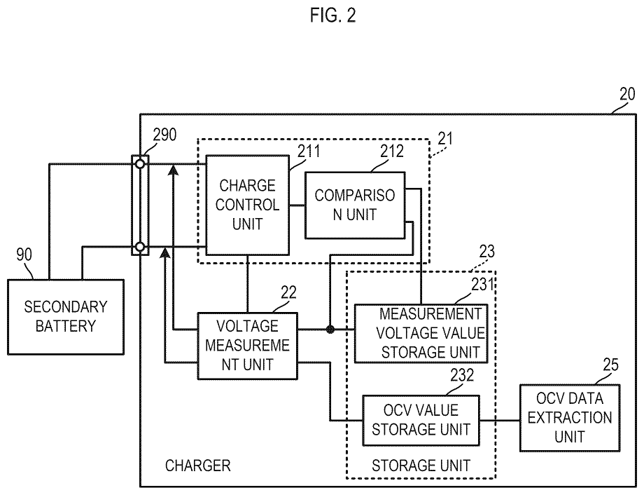

FIG. 2 is a configuration diagram of a charging system including a charger and a secondary battery according to an embodiment of the present disclosure and capable of acquiring OCV data.

As illustrated in FIG. 2, a charger 20 includes a control unit 21, a voltage measurement unit 22, a storage unit 23, an OCV data extraction unit 25, and a charging terminal 290. The control unit 21 includes a charge control unit 211 and a comparison unit 212.

The control unit 21 is realized by, for example, an electric and electronic circuit in which an arithmetic processing unit such as an MPU and a power supply circuit are combined. The voltage measurement unit 22 is realized by a DC voltmeter. The storage unit 23 is realized by various memories. Similarly to the control unit 21, the OCV data extraction unit 25 is realized by an arithmetic processing unit or the like. Although not illustrated, each functional unit of the charger 20 is supplied with power from a commercial power supply or the like.

A secondary battery 90 is, for example, a lithium ion secondary battery. The secondary battery 90 can be charged by being connected to the charging terminal 290.

The charger 20 sets one cycle of a pair of the first mode and the second mode for acquisition of the SOC-OCV characteristic of the secondary battery 90. The charger 20 charges the secondary battery 90 connected to the charging terminal 290 by repeating the one-cycle process from a state where the secondary battery 90 is not charged at all to a fully charged state.

At this time, the charger 20 measures the OCV value every cycle of the secondary battery 90. The charger 20 extracts the OCV data for obtaining the SOC-OCV characteristic using the measured OCV value (a plurality of OCV values) in each cycle.

More specifically, the charger 20 executes the following processing.

### First Mode

The charge control unit 211 charges the secondary battery 90 at a predetermined constant current value.

The voltage measurement unit 22 constantly measures the terminal voltage value of the secondary battery 90. The control unit 21 performs charging in the first mode until a predetermined voltage change is measured, and then switches to the second mode.

In addition, the voltage measurement unit 22 outputs the terminal voltage value α measured at the timing closest to the timing of switching from the first mode to the second mode to a measurement voltage value storage unit 231 of the storage unit 23. The measurement voltage value storage unit 231 stores the input terminal voltage value α as the terminal voltage value αB measured in the first mode one cycle before.

The comparison unit 212 compares a difference value (αA−αB) between the terminal voltage value α of the current cycle measured by the voltage measurement unit 22 and the terminal voltage value αB measured in the first mode one cycle before with a switching reference value TH.

In the comparison unit 212, the switching reference value TH for determining the switching timing from the first mode to the second mode is a voltage value, and is a value obtained by dividing a difference value between the maximum value and the minimum value of the OCV by an integer n determined based on the number of acquired SOC data.

When the difference value (αA−αB) reaches the switching reference value TH, the comparison unit 212 outputs a stop instruction of the first mode to the charge control unit 211. The charge control unit 211 stops charging with this stop instruction as a trigger. As a result, the first mode in one cycle ends and is switched to the second mode.

### Second Mode

The charge control unit 211 suspends charging of the secondary battery 90 during the period of the second mode (suspension time). The time length of the suspension time is set to a time required until the overvoltage due to the internal resistance of the secondary battery 90 is alleviated.

The voltage measurement unit 22 measures the terminal voltage value after the elapse of the suspension time, and outputs the terminal voltage value as the OCV value β. The voltage measurement unit 22 stores the OCV value β in an OCV value storage unit 232 of the storage unit 23.

The OCV value storage unit 232 of the storage unit 23 stores the OCV value β measured in the second mode in each cycle in association with the capacity value charged in the first mode. The capacity value is obtained from the product of the charged current and time.

### Extraction of OCV Data

When detecting the elapse of the suspension time, the control unit 21 ends the second mode and returns to the first mode. The control unit 21 repeats the cycle including the pair of the first mode and the second mode until the detection of the fully charged state based on the terminal voltage value αA.

As a result, the OCV value storage unit 232 of the storage unit 23 stores the OCV values at a plurality of measurement points obtained by dividing the time when the secondary battery 90 is empty and the time when the secondary battery is fully charged by voltages at equal intervals. As described above, since the empty voltage and the full-charge voltage are not affected by the deterioration degree, the number of measurement points of the OCV value does not change without being affected by the deterioration degree of the secondary battery 90.

The OCV data extraction unit 25 collectively extracts the OCV values at the plurality of measurement points stored in the OCV value storage unit 232 as OCV data.

In the conventional intermittent charging at a constant current time, it is equivalent to setting the measurement point based on the horizontal axis in FIG. 1C, the number of measurement points varies according to the deterioration degree, and the number of measurement points decreases as the deterioration degree increases.

On the other hand, the charger 20 uses the difference value between the terminal voltage values as a reference for switching between the first mode and the second mode, thereby becoming equivalent to setting the measurement point with reference to the vertical axis of FIG. 1C. Although the time required for the first mode changes every cycle, the number of measurement points does not change according to the deterioration degree, and a decrease in the number of measurement points is suppressed.

As a result, the charger 20 can measure the OCV value without depending on the deterioration degree and without reducing the number of measurement points of the OCV value for obtaining the SOC-OCV characteristic.

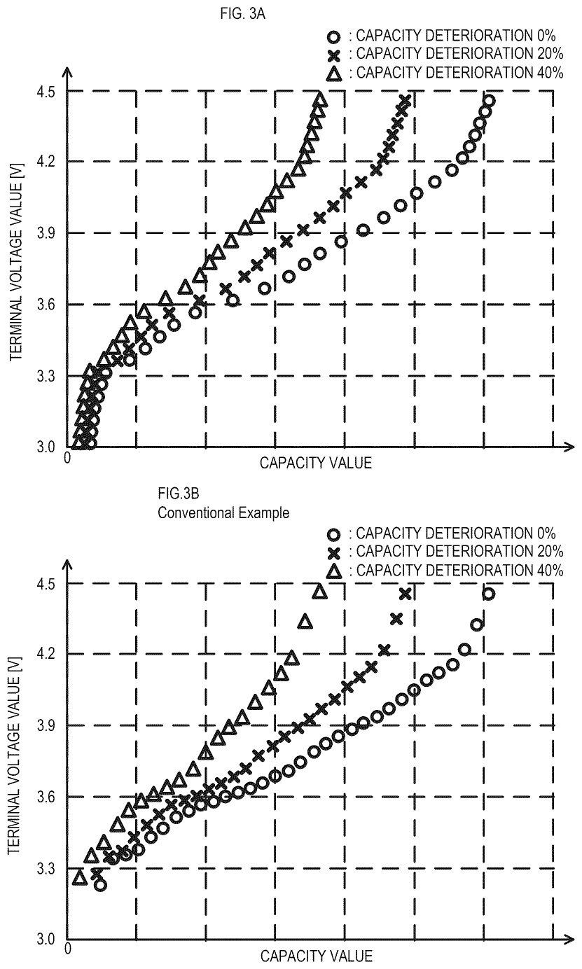

FIG. 3A is a graph illustrating an example of a distribution of measurement points of the present disclosure; and FIG. 3B is a graph illustrating an example of a distribution of measurement points of a conventional example. In FIGS. 3A and 3B, the horizontal axis represents the capacity value of the secondary battery, and the vertical axis represents the terminal voltage value. In FIGS. 3A and 3B, ○ indicates a measurement point at which the capacity deterioration of the secondary battery is 0% (before deterioration), × indicates a measurement point at which the capacity deterioration of the secondary battery is 20%, and Δ indicates a measurement point at which the capacity deterioration of the secondary battery is 40%. In the conventional example, the control at the constant current time is used.

As illustrated in FIG. 3A, in an embodiment of the present disclosure, the number of measurement points does not change without being affected by capacity deterioration (deterioration degree) of the secondary battery. On the other hand, in the conventional example as illustrated in FIG. 3B, the number of measurement points decreases as the capacity deterioration (deterioration degree) of the secondary battery increases.

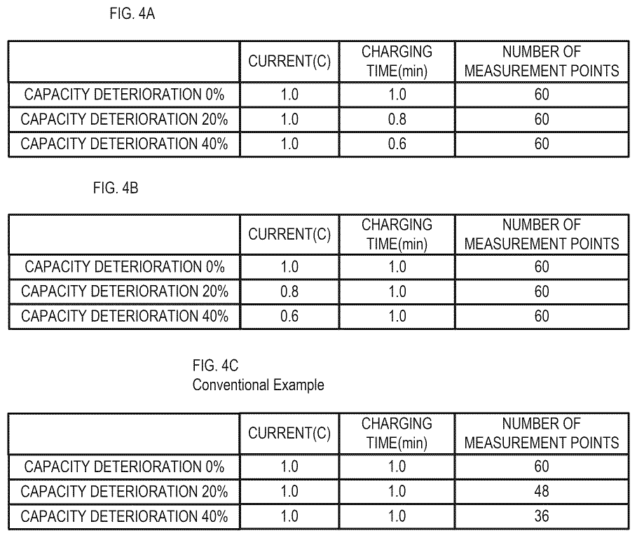

FIGS. 4A and 4B illustrate tables showing the relationship between the combination of the current and the charging time and the number of measurement points according to an embodiment of the present disclosure; and FIG. 4C illustrates a table showing the relationship between the combination of the current and the charging time and the number of measurement points in the conventional example. FIGS. 4A and 4B show, according to an embodiment of the present disclosure, two types of modes of adjusting the charging time and adjusting the charging current. The mode of adjusting the charging time corresponds to the mode described above. The conventional example of FIG. 4C is the same as the conventional example of FIG. 3B.

As illustrated in FIGS. 4A and 4B, in an embodiment of the present disclosure, the number of measurement points does not change without being affected by capacity deterioration (deterioration degree) of the secondary battery. On the other hand, in the conventional example, the number of measurement points decreases as the capacity deterioration (deterioration degree) of the secondary battery increases.

As described above, the charger 20 of the present disclosure can measure the OCV value without depending on the deterioration degree and without reducing the number of measurement points of the OCV value for obtaining the SOC-OCV characteristic.

As illustrated in FIGS. 4A and 4B, the charging current in the first mode may be adjusted. Also in this mode, the charger 20 can measure the OCV value without depending on the deterioration degree and without reducing the number of measurement points of the OCV value for obtaining the SOC-OCV characteristic.

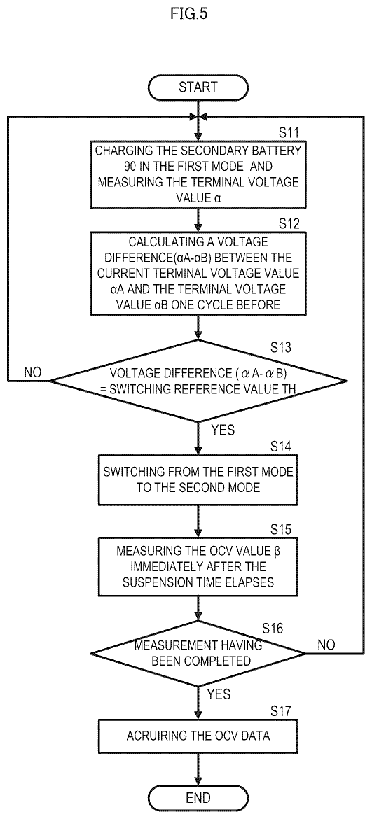

FIG. 5 is a flowchart illustrating an example of an OCV data acquisition method according to an embodiment of the present disclosure. Note that, since the specific description of each processing of the flowchart illustrated in FIG. 5 has been made in the description of the above-described configuration, detailed description thereof is omitted here except for necessary portions. Although the charger 20 will be mainly described below, each process is performed by each functional unit constituting the charger 20 as described above.

The charger 20 measures the terminal voltage value α while charging the secondary battery 90 in the first mode (S11). The charger 20 calculates a voltage difference (αA−αB) between the current terminal voltage value αA and the terminal voltage value αB one cycle before (S12). If the voltage difference has not reached the switching reference value TH (S13: NO), the charger 20 continues the first mode.

When the voltage difference reaches the switching reference value TH (S13: YES), the charger 20 switches from the first mode to the second mode (S14).

Upon shifting to the second mode, the charger 20 suspends charging for the suspension time, and measures the OCV value β immediately after the suspension time elapses (S15).

After measuring all the OCV values β within the SOC range used for the OCV analysis, the charger 20 completes the measurement. For example, when the charging upper limit voltage of the secondary battery 90 is reached, the charger 20 is controlled so as not to exceed the upper limit voltage while appropriately reducing the charging current, and the measurement is completed after the current value reaches the current value under the stop condition. If the measurement has not been completed (S16: NO), the charger 20 returns to the first mode and continues charging and measurement.

When the measurement is completed (S16: YES), the charger 20 acquires (extracts) the OCV data using the plurality of OCV values β measured in the process of charging described above (S17).

By using such a method, the OCV data acquisition method can measure the OCV value without depending on the deterioration degree and without reducing the number of measurement points of the OCV value for obtaining the SOC-OCV characteristic.

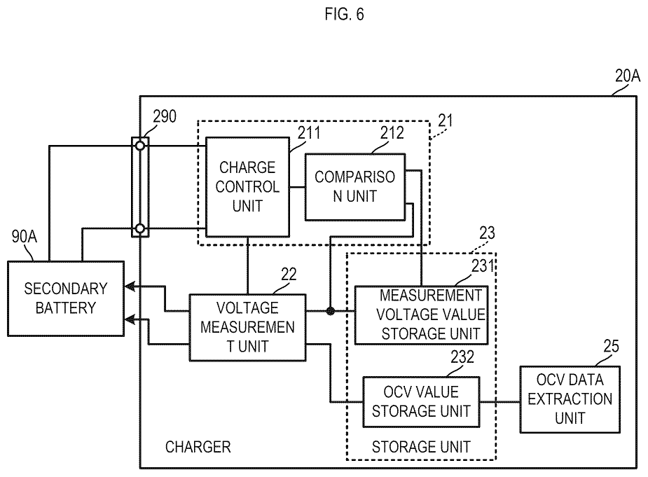

FIG. 6 is a configuration diagram of a charging system capable of acquiring OCV data including a secondary battery including a voltage value output terminal.

As illustrated in FIG. 6, the charging system includes a charger 20A and a secondary battery 90A. The secondary battery 90A includes a voltage value output terminal that outputs a voltage value of a battery cell (not illustrated) constituting the secondary battery 90A.

In this case, the voltage measurement unit 22 of the charger 20A is connected to the voltage value output terminal of the charger 20A and measures the output voltage.

Even with such a configuration, similar functions and effects can be achieved.

The present disclosure is described below in further details according to an embodiment.
<1> A charger including:
   a control unit that controls charging of a lithium ion secondary battery when the lithium ion secondary battery is attached to the charger;
   a voltage measurement unit that measures a terminal voltage of the lithium ion secondary battery during the charging; and
   an OCV data extraction unit that extracts OCV data available for analysis of a deterioration degree of the lithium ion secondary battery, in which
   a first mode and a second mode are provided as one cycle of charging of the lithium ion secondary battery,
   in the first mode,
   the control unit charges the lithium ion secondary battery with a predetermined current value,
   the voltage measurement unit measures a terminal voltage value α of the lithium ion secondary battery, and
   the control unit and the voltage measurement unit shift to the second mode after end of the first mode,
   in the second mode,
   the control unit suspends charging for a predetermined suspension time,
   the voltage measurement unit measures an OCV value β of the lithium ion secondary battery immediately after an elapse of the suspension time, and
   the control unit and the voltage measurement unit return to the first mode after end of the second mode, and
   the control unit is configured to execute:
   comparing a terminal voltage value αA acquired by the first mode with a terminal voltage value αB acquired by the first mode one cycle before; and
   controlling charging in the first mode such that a difference value between the terminal voltage value αA and the terminal voltage value αB becomes a constant value, and
   the OCV data extraction unit extracts the OCV data using an OCV value β measured in each of a plurality of cycles.
<2> The charger according to <1>, in which
   the control unit adjusts a charging time or a charging current for each cycle.
<3> An OCV data acquisition method for causing a charger to execute:
   controlling charging of a lithium ion secondary battery so as to have a first mode and a second mode as one cycle of charging of the lithium ion secondary battery when the lithium ion secondary battery is attached;
   in the first mode,
   charging the lithium ion secondary battery at a predetermined current value,
   measuring a terminal voltage value α of the lithium ion secondary battery, and
   shifting to a second mode after end of the first mode; and
   in the second mode,
   suspending charging for a predetermined suspension time,
   measuring an OCV value β of the lithium ion secondary battery immediately after an elapse of the suspension time,
   returning to the first mode after end of the second mode,
   comparing a terminal voltage value αA acquired by the first mode with a terminal voltage value αB acquired by the first mode one cycle before,
   controlling charging in the first mode such that a difference value between the terminal voltage value αA and the terminal voltage value αB becomes a constant value, and
   extracting OCV data using the OCV value β measured in each of the plurality of cycles.
<4> The OCV data acquisition method according to <3>, in which
   the charger adjusts a charging time or a charging current for each cycle.

### REFERENCE SIGNS LIST

20, 20A charger
21 control unit
22 voltage measurement unit
23 storage unit
25 OCV data extraction unit
90, 90A secondary battery
211 charge control unit
212 comparison unit
231 measurement voltage value storage unit
232 OCV value storage unit
290 charging terminal

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A charger comprising:
a control unit that controls charging of a lithium ion secondary battery when the lithium ion secondary battery is attached to the charger;
a voltage measurement unit that measures a terminal voltage of the lithium ion secondary battery during the charging; and
an OCV data extraction unit that extracts OCV data available for analysis of a deterioration degree of the lithium ion secondary battery, wherein
a first mode and a second mode are provided as one cycle of charging of the lithium ion secondary battery,
in the first mode,
the control unit charges the lithium ion secondary battery with a predetermined current value,
the voltage measurement unit measures a terminal voltage value α of the lithium ion secondary battery, and
the control unit and the voltage measurement unit shift to the second mode after end of the first mode,
in the second mode,
the control unit suspends charging for a predetermined suspension time,
the voltage measurement unit measures an OCV value β of the lithium ion secondary battery immediately after an elapse of the suspension time, and
the control unit and the voltage measurement unit return to the first mode after end of the second mode, and
the control unit is configured to execute:
comparing a terminal voltage value αA acquired by the first mode with a terminal voltage value αB acquired by the first mode one cycle before; and
controlling charging in the first mode such that a difference value between the terminal voltage value αA and the terminal voltage value αB becomes a constant value, and
the OCV data extraction unit extracts the OCV data using an OCV value β measured in each of a plurality of cycles.

2. The charger according to claim 1, wherein
the control unit adjusts a charging time or a charging current for each cycle.

3. An OCV data acquisition method for causing a charger to execute:
controlling charging of a lithium ion secondary battery so as to have a first mode and a second mode as one cycle of charging of the lithium ion secondary battery when the lithium ion secondary battery is attached;
in the first mode,
charging the lithium ion secondary battery at a predetermined current value,
measuring a terminal voltage value α of the lithium ion secondary battery, and
shifting to a second mode after end of the first mode; and
in the second mode,
suspending charging for a predetermined suspension time,
measuring an OCV value β of the lithium ion secondary battery immediately after an elapse of the suspension time,
returning to the first mode after end of the second mode,
comparing a terminal voltage value αA acquired by the first mode with a terminal voltage value αB acquired by the first mode one cycle before,
controlling charging in the first mode such that a difference value between the terminal voltage value αA and the terminal voltage value αB becomes a constant value, and
extracting OCV data using the OCV value β measured in each of the plurality of cycles.

4. The OCV data acquisition method according to claim 3, wherein
the charger adjusts a charging time or a charging current for each cycle.
